(19) United States
(12) Patent Application Publication
(10) Pub. No.: US 2015/0070100 A1
(43) Pub. Date: Mar. 12, 2015

(54) SEMICONDUCTOR INTEGRATED CIRCUIT AND OSCILLATION SYSTEM

(71) Applicant: KABUSHIKI KAISHA TOSHIBA, Tokyo (JP)

(72) Inventors: Hiroaki Shimizu, Tokyo (JP); Akihiko Kaneko, Tokyo (JP)

(73) Assignee: KABUSHIKI KAISHA TOSHIBA, Tokyo (JP)

(21) Appl. No.: 14/185,211

(22) Filed: Feb. 20, 2014

(30) Foreign Application Priority Data
Sep. 11, 2013 (JP) 2013-188380

(51) Int. Cl. H03B 5/36; H03L 5/00

(52) U.S. Cl. CPC H03B 5/364; H03L 5/00
USPC 331/109

(57) ABSTRACT

The semiconductor integrated circuit includes an inverting amplifier that generates an oscillation signal with an input connected to the first terminal and an output connected to the second terminal, the inverting amplifier fluctuating in gain in response to a gain control signal. The semiconductor integrated circuit includes a waveform shaping circuit that shapes a waveform of the oscillation signal and outputs a clock signal to a clock signal output terminal. The semiconductor integrated circuit includes an edge detecting circuit that detects an edge of the clock signal and outputs the gain control signal at a time of the edge.

### CROSS-REFERENCE TO RELATED APPLICATION

This application is based upon and claims the benefit of priority from the prior Japanese Patent Application No. 2013-188380, filed on Sep. 11, 2013, the entire contents of which are incorporated herein by reference.

### BACKGROUND

1. Field

Embodiments described herein relate generally to a semiconductor integrated circuit and an oscillation system.

2. Background Art

A conventional oscillation system of a crystal resonator includes, for example, an oscillation circuit in which a crystal resonator is connected between the input and output ends of an inverter amplifier provided with positive feedback from a feedback resistor. A load capacitance is connected between both ends of the crystal resonator and the ground.

In this case, the current consumption of the oscillation circuit is determined by the value of the load capacitance and the intensity of oscillation. A large amount of current consumption is necessary for stably operating the crystal resonator that requires a load capacitance having a large capacitance value.

Even if a used crystal resonator only requires a load capacitance having a small capacitance value, an inverter and a resistor have fixed values, demanding a large amount of current consumption.

### BRIEF DESCRIPTION OF THE DRAWINGS

FIG. 1 is a circuit diagram illustrating an example of the configuration of an oscillation system 100 according to a first embodiment;

FIG. 2 is a waveform chart showing an example of a power supply voltage VDD and the gain control signal GS when the capacitance values of the first load capacitance C1 and the second load capacitance C2 are not lower than the predetermined threshold;

FIG. 3 is a waveform chart showing an example of the power supply voltage VDD and the gain control signal GS when the capacitance values of the first load capacitance C1 and the second load capacitance C2 are lower than the predetermined threshold;

FIG. 4 is a circuit diagram illustrating an example of the configuration of an oscillation system 200 according to a second embodiment; and

FIG. 5 is a circuit diagram illustrating an example of the circuit configuration of the auxiliary inverter IN2 in FIG. 4.

### DETAILED DESCRIPTION

A semiconductor integrated circuit, according to an embodiment, controls oscillation of a crystal resonator. The semiconductor integrated circuit is applied to an oscillation system comprising a first load capacitance with a first end connected to ground and a second end connected to a first terminal, a second load capacitance with a first end connected to the ground and a second end connected to a second terminal, and a crystal resonator with a first end connected to the second end of the first load capacitance and a second end connected to the second end of the second load capacitance.

The semiconductor integrated circuit includes an inverting amplifier that generates an oscillation signal with an input connected to the first terminal and an output connected to the second terminal, the inverting amplifier fluctuating in gain in response to a gain control signal. The semiconductor integrated circuit includes a waveform shaping circuit that shapes a waveform of the oscillation signal and outputs a clock signal to a clock signal output terminal. The semiconductor integrated circuit includes an edge detecting circuit that detects an edge of the clock signal and outputs the gain control signal at a moment of the edge.

The edge detecting circuit outputs the gain control signal that sets the gain of the inverting amplifier at a first value in case of the first and the second load capacitance not exceed predetermined threshold.

The edge detecting circuit outputs the gain control signal that sets the gain of the inverting amplifier at a second value lower than the first value if the capacitance values are lower than the predetermined threshold.

Embodiments will be described below with reference to the accompanying drawings.

### First Embodiment

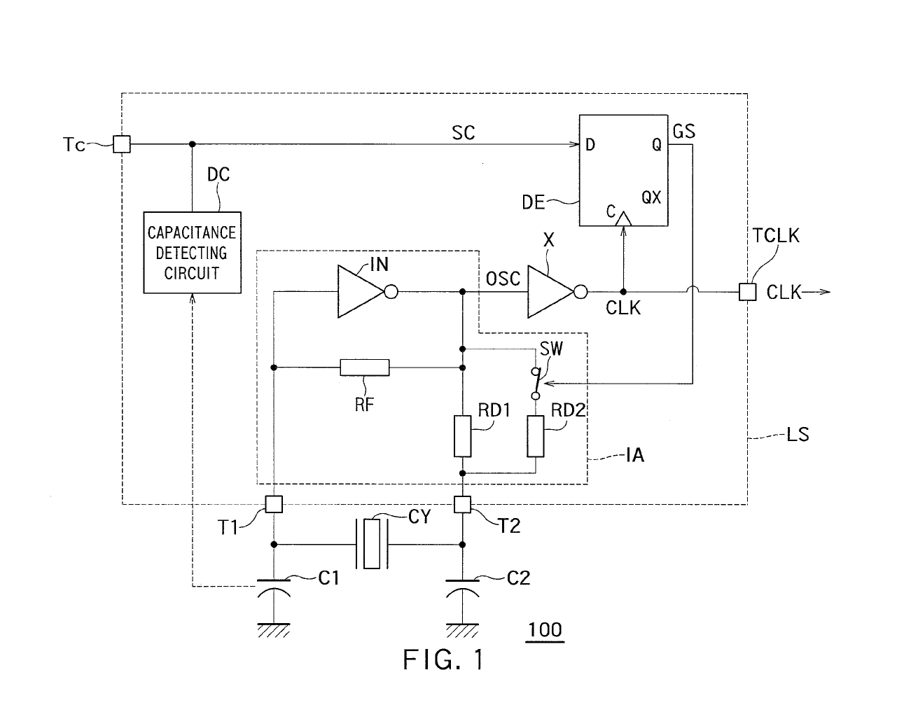

FIG. 1 is a circuit diagram illustrating an example of the configuration of an oscillation system 100 according to a first embodiment.

As shown in FIG. 1, the oscillation system 100 includes a first load capacitance C1, a second load capacitance C2, a crystal resonator CY, and a semiconductor integrated circuit LS.

The first load capacitance C1 has one end connected to the ground and the other end connected to a first terminal T1.

The second load capacitance C2 has one end connected to the ground and the other end connected to a second terminal T2.

The crystal resonator CY has one end connected to the other end of the first load capacitance C1 and the other end connected to the other end of the second load capacitance C2. The semiconductor integrated circuit LS is applied to the oscillation system 100 to control the oscillation of the crystal resonator CY.

As shown in FIG. 1, the semiconductor integrated circuit LS includes, for example, an inverting amplifier IA, a waveform shaping circuit X, an edge detecting circuit DE, and a capacitance detecting circuit DC. As will be described later, if a capacitance information signal SC is fed from the outside, the capacitance detecting circuit DC may be omitted.

The inverting amplifier IA has its input connected to the first terminal T1 and its output connected to the second terminal T2. The inverting amplifier IA generates an oscillation signal OSC and has a gain fluctuating in response to a gain control signal GS.

The waveform shaping circuit X outputs a clock signal CLK, which is obtained by shaping the waveform of the oscillation signal OSC, to a clock output terminal TCLK.

As shown in FIG. 1, the waveform shaping circuit X is, for example, an inverter that receives the oscillation signal OSC from its input and outputs the clock signal CLK from its output.

The capacitance detecting circuit DC detects the capacitance values of the first load capacitance C1 and the second load capacitance C2 and outputs a capacitance information signal SC that determines whether or not the capacitance values are lower than the predetermined threshold. For example, the capacitance information signal SC may be fed to the edge detecting circuit DE from the outside of the semiconductor integrated circuit LS through a capacitance information terminal TC. In this case, the capacitance detecting circuit DC may be omitted.

The edge detecting circuit DE detects the edge of the clock signal CLK. Furthermore, the edge detecting circuit DE generates the gain control signal GS based on the capacitance information signal SC that determines whether or not the capacitance values of the first load capacitance C1 and the second load capacitance C2 are lower than the predetermined threshold.

For example, if the capacitance values of the first load capacitance C1 and the second load capacitance C2 are not lower than the predetermined threshold, the edge detecting circuit DE outputs, when the edge of the clock signal CLK is detected, the gain control signal GS that sets the gain of the inverting amplifier IA at a first value.

If the capacitance values are lower than the predetermined threshold, the edge detecting circuit DE outputs, when the edge of the clock signal CLK is detected, the gain control signal GS that sets the gain of the inverting amplifier IA at a second value lower than the first value.

The edge detecting circuit DE outputs the gain control signal GS that sets the gain of the inverting amplifier IA at the first value, for example, at the start of power supply to the semiconductor integrated circuit LS.

As shown in FIG. 1, the edge detecting circuit DE is, for example, a flip-flop circuit that receives a capacitance detection signal from a data terminal D, receives the clock signal CLK from a clock signal terminal C, and outputs the gain control signal GS from an output Q.

As shown in FIG. 1, the inverting amplifier IA includes, for example, an inverter IN, a feedback resistor RF, a first damping resistor RD1, a second damping resistor RD2, and a switch element SW.

The inverter IN has its input connected to the first terminal T1 and outputs the oscillation signal OSC.

The feedback resistor RF has one end connected to the input of the inverter. IN and the other end connected to the output of the inverter IN.

The first damping resistor RD1 has one end connected to the output of the inverter IN and the other end connected to the second terminal T2.

The second damping resistor RD2 is connected in parallel with the first damping resistor RD1 between the output of the inverter IN and the second terminal T2.

The switch element SW is connected in series with the second damping resistor RD2 between the output of the inverter IN and the second terminal T2. The switch element SW is turned on/off in response to the gain control signal GS.

For example, if the capacitance values are not lower than the predetermined threshold, the switch element SW is continuously turned on in response to the gain control signal GS.

Thus, in the use of the crystal resonator CY requiring the first and second load capacitances C1 and C2 having large capacitance values, the first damping resistor RD1 and the second damping resistor RD2 are connected in parallel to reduce the value of the damping resistor. This keeps a state of increased intensity of oscillation (the gain of the inverting amplifier IA is set at the first value).

If the capacitance values are lower than the predetermined threshold, the switch element SW is turned off in response to the gain control signal GS.

In the case of the crystal resonator CY only requiring the first and second load capacitances C1 and C2 having small capacitance values, the first damping resistor RD1 is caused to act as a damping resistor. This action makes the circuit to the lighter oscillating ability (the gain of the inverting amplifier IA changes to the second value), thereby the current consumption of the inverting amplifier IA is suppressed.

The switch element SW is turned on in response to the gain control signal GS, for example, at the start of power supply to the semiconductor integrated circuit LS.

Thus, at the start of power supply to the semiconductor integrated circuit LS, the switch element SW is controlled to a state of increased intensity of oscillation (the gain of the inverting amplifier IA is set at the first value).

As described above, if the capacitance values are lower than the predetermined threshold, the edge detecting circuit DE outputs, when the edge of the clock signal CLK is detected, the gain control signal GS that sets the gain of the inverting amplifier IA at the second value lower than the first value.

Hence, the gain of the inverting amplifier IA is always switched at the same timing relative to the oscillation signal OSC (the zero cross point of the oscillation signal OSC). This can prevent an unstable operation at the switching of the inverting amplifier IA.

The output of the flip-flop circuit (the gain control signal GS) changes in synchronization with the oscillation signal OSC (clock signal CLK). Thus, the gain of the inverting amplifier IA can be always switched at the same timing (the zero cross point of the oscillation signal OSC) relative to one period of the oscillation signal OSC.

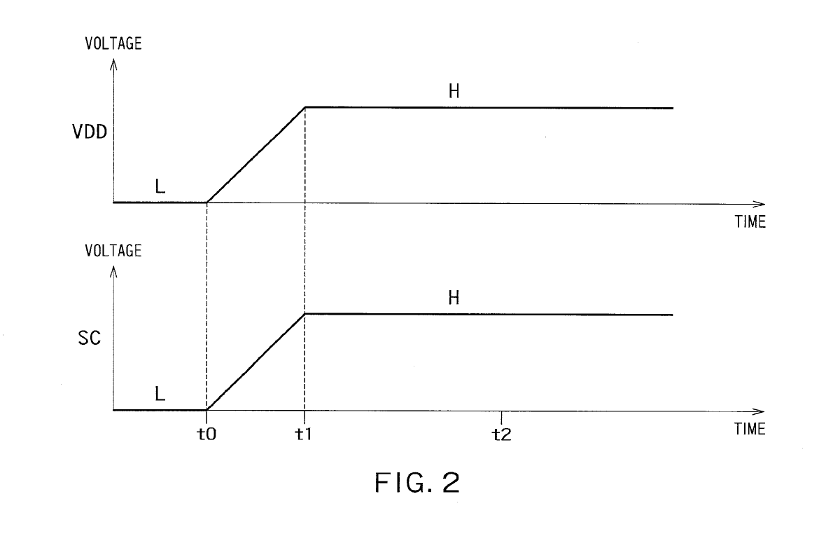

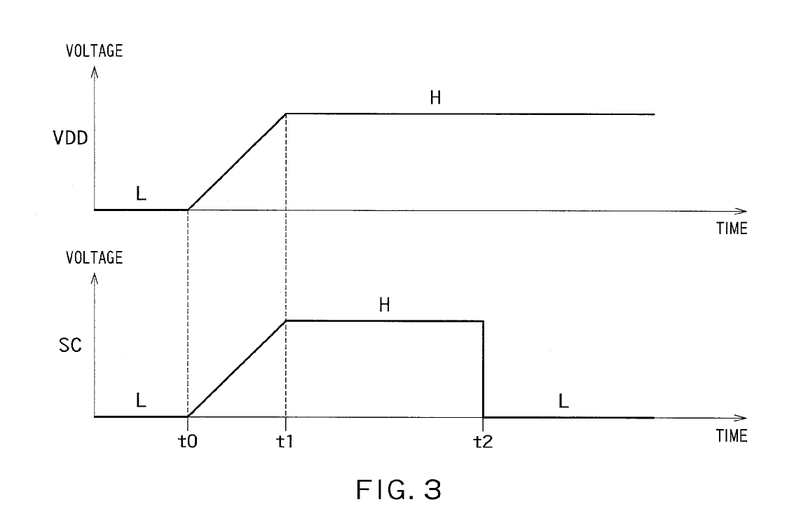

An example of the operation of the oscillation system 100 configured thus will be described below. FIG. 2 is a waveform chart showing an example of a power supply voltage VDD and the gain control signal GS when the capacitance values of the first load capacitance C1 and the second load capacitance C2 are not lower than the predetermined threshold. FIG. 3 is a waveform chart showing an example of the power supply voltage VDD and the gain control signal GS when the capacitance values of the first load capacitance C1 and the second load capacitance C2 are lower than the predetermined threshold.

As shown in FIG. 2, for example, if the capacitance values of the first load capacitance C1 and the second load capacitance C2 are not lower than the predetermined threshold, power supply at time t0 increases the power supply voltage VDD. The voltage level of the gain control signal GS also increases in synchronization with an increase in the power supply voltage VDD. When the voltage level of the gain control signal GS rises to “High” level (time t1), the switch element SW is turned on. Thus, the gain of the inverting amplifier IA is set at the first value.

As described above, the edge detecting circuit DE outputs the gain control signal GS that sets the gain of the inverting amplifier IA at the first value, for example, at the start of power supply to the semiconductor integrated circuit LS.

After that, for example, the capacitance values of the first load capacitance C1 and the second load capacitance C2 are not lower than the predetermined threshold. Thus, when the edge of the clock signal CLK is detected (time t2), the edge detecting circuit DE outputs the gain control signal GS that sets the gain of the inverting amplifier IA at the first value.

As described above, in the use of the crystal resonator CY requiring the first and second load capacitances C1 and C2 having large capacitance values, the first damping resistor RD1 and the second damping resistor RD2 are connected in parallel to reduce the value of the damping resistor. This keeps a state of increased intensity of oscillation (the gain of the inverting amplifier IA is set at the first value).

As shown in FIG. 3, for example, if the capacitance values of the first load capacitance C1 and the second load capacitance C2 are lower than the predetermined threshold, the power supply voltage VDD increases at power-on at time t0. Moreover, the voltage level of the gain control signal GS increases in synchronization with the increase in the power supply voltage VDD. When the voltage level of the gain control signal GS rises to “High” level (time t1), the switch element SW is turned on. Thus, the gain of the inverting amplifier IA is set at the first value.

After that, for example, the capacitance values of the first load capacitance C1 and the second load capacitance C2 are lower than the predetermined threshold. Thus, when the edge of the clock signal CLK is detected (time t2), the edge detecting circuit DE outputs the gain control signal GS (the voltage level is “Low”) that sets the gain of the inverting amplifier IA at the second value lower than the first value.

As described above, in the use of the crystal resonator CY only requiring the first and second load capacitances C1 and C2 having small capacitance values, the first damping resistor RD1 is caused to act as a damping resistor. This action makes the circuit to the lighter oscillating ability (the gain of the inverting amplifier IA changes to the second value), thereby the current consumption of the inverting amplifier IA is suppressed.

As described above, the semiconductor integrated circuit LS according to the first embodiment can reduce current consumption.

### Second Embodiment

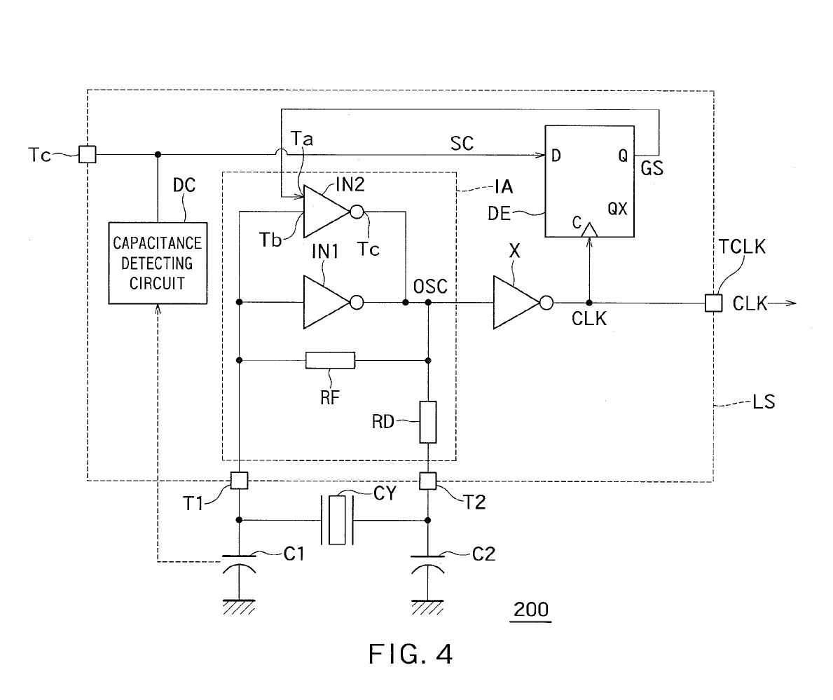

FIG. 4 is a circuit diagram illustrating an example of the configuration of an oscillation system 200 according to a second embodiment. In FIG. 4, the same reference numerals as in FIG. 1 indicate the same configurations as in the first embodiment and the explanation thereof is omitted.

As shown in FIG. 4, as in the first embodiment, the oscillation system 200 includes a first load capacitance C1, a second load capacitance C2, a crystal resonator CY, and a semiconductor integrated circuit LS.

As shown in FIG. 4, an inverting amplifier IA includes, for example, an inverter IN1, an auxiliary inverter IN2, and a damping resistor RD.

The inverter IN1 has its input connected to a first terminal T1 and outputs an oscillation signal OSC.

The auxiliary inverter IN2 receives a gain control signal GS from an input Ta, has an input Tb connected to the input of the inverter IN1, and has an output Tc connected to the output of the inverter IN1.

For example, if the capacitance values of the first load capacitance C1 and the second load capacitance C2 are not lower than a predetermined threshold, the auxiliary inverter IN2 is kept driven in response to the gain control signal GS.

If the capacitance values of the first load capacitance C1 and the second load capacitance C2 are lower than the predetermined threshold, driving of the auxiliary inverter IN2 is stopped in response to the gain control signal GS.

The auxiliary inverter IN2 is controlled to a driven state in response to the gain control signal GS, for example, at the start of power supply to the semiconductor integrated circuit LS.

A feedback resistor RF has one end connected to the input of the inverter IN1 and the other end connected to the output of the inverter IN1.

The damping resistor RD has one end connected to the output of the inverter IN1 and the other end connected to a second terminal T2.

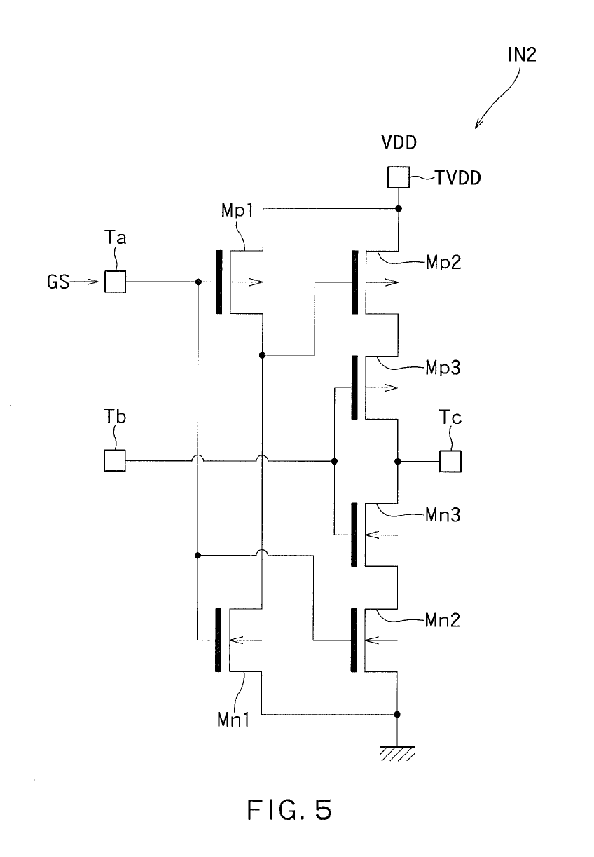

FIG. 5 is a circuit diagram illustrating an example of the circuit configuration of the auxiliary inverter IN2 in FIG. 4.

As shown in FIG. 5, the auxiliary inverter IN2 includes, for example, a first pMOS transistor Mp1, a second pMOS transistor Mp2, a third pMOS transistor Mp3, a first nMOS transistor Mn1, a second nMOS transistor Mn2, and a third nMOS transistor Mn3.

The first pMOS transistor Mp1 has its source connected to a power supply terminal TVDD that receives a power supply voltage VDD, and has its gate fed with the gain control signal GS.

The first nMOS transistor Mn1 has its source connected to the ground, its drain connected to the drain of the first pMOS transistor Mp1, and its gate fed with the gain control signal GS.

The second pMOS transistor Mp2 has its source connected to the power supply terminal TVDD and its gate connected to the drain of the first pMOS transistor Mp1.

The third pMOS transistor Mp3 has its source connected to the drain of the second pMOS transistor Mp2, its drain connected to the output of the inverter IN1, and its gate connected to the first terminal T1.

The second nMOS transistor Mn2 has its source connected to the ground and its gate connected to the gate of the first nMOS transistor Mn1.

The third nMOS transistor Mn3 has its source connected to the drain of the second nMOS transistor Mn2, its drain connected to the output of the inverter IN1, and its gate connected to the first terminal T1.

For example, if the capacitance values of the first load capacitance C1 and the second load capacitance C2 are not lower than a predetermined threshold, the gain control signal GS rises to “High” level. Thus, the second pMOS transistor Mp2 and the second nMOS transistor Mn2 are turned on. This allows the third pMOS transistor Mp3 and the third nMOS transistor Mn3 to act as inverter amplifiers. Hence, the auxiliary inverter IN2 inverts and amplifies a signal supplied to the input Tb and then outputs the signal from the output Tc.

In the use of the crystal resonator CY requiring the first and second load capacitances C1 and C2 having large capacitance values, the inverter IN1 and the auxiliary inverter IN2 are simultaneously operated. Thus, the intensity of oscillation is controlled to increase the intensity (the gain of the inverting amplifier IA is set at a first value).

If the capacitance values of the first load capacitance C1 and the second load capacitance C2 are lower than the predetermined threshold, the gain control signal GS decreases to “Low” level. Thus, the second pMOS transistor Mpg and the second nMOS transistor Mn2 are turned off. This prevents the third pMOS transistor Mp3 and the third nMOS transistor Mn3 from acting as inverter amplifiers. Thus, the auxiliary inverter IN2 does not invert or amplify the signal fed to the input Tb and does not output the signal from the output Tc.

In the use of the crystal resonator CY only requiring the first and second load capacitances C1 and C2 having small capacitance values, the operation of the auxiliary inverter IN2 is stopped. This action makes the circuit to the lighter oscillating ability (the gain of the inverting amplifier IA changes to the second value), thereby the current consumption of the inverting amplifier IA is suppressed.

Other configurations of the semiconductor integrated circuit 200 are identical to those of the semiconductor integrated circuit 100 according to the first embodiment. Other operations of the semiconductor integrated circuit 200 are identical to those of the semiconductor integrated circuit 100 according to the first embodiment.

In other words, the semiconductor integrated circuit according to the second embodiment can reduce current consumption as in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor integrated circuit that controls oscillation of a crystal resonator, the semiconductor integrated circuit being applied to an oscillation system comprising a first load capacitance with a first end connected to ground and a second end connected to a first terminal, a second load capacitance with a first end connected to the ground and a second end connected to a second terminal, and a crystal resonator with a first end connected to the second end of the first load capacitance and a second end connected to the second end of the second load capacitance,
the semiconductor integrated circuit comprising:
an inverting amplifier that generates an oscillation signal with an input connected to the first terminal and an output connected to the second terminal, the inverting amplifier fluctuating in gain in response to a gain control signal;
a waveform shaping circuit that shapes a waveform of the oscillation signal and outputs a clock signal to a clock signal output terminal; and
an edge detecting circuit that detects an edge of the clock signal and outputs the gain control signal at a time of the edge,
wherein the edge detecting circuit outputs the gain control signal that sets the gain of the inverting amplifier at a first value if capacitance values of the first load capacitance and the second load capacitance are not lower than a predetermined threshold, and
the edge detecting circuit outputs the gain control signal that sets the gain of the inverting amplifier at a second value lower than the first value if the capacitance values are lower than the predetermined threshold.

2. The semiconductor integrated circuit according to claim 1, wherein the inverting amplifier comprises:
an inverter that outputs the oscillation signal with an input connected to the first terminal;
a feedback resistor with a first end connected to the input of the inverter and a second end connected to an output of the inverter;
a first damping resistor with a first end connected to the output of the inverter and a second end connected to the second terminal;
a second damping resistor connected in parallel with the first damping resistor between the output of the inverter and the second terminal; and
a switch element connected in series with the second damping resistor between the output of the inverter and the second terminal, the switch element being turned on/off in response to the gain control signal,
wherein the switch element is turned on in response to the gain control signal if the capacitance values are not lower than the predetermined threshold, and
the switch element is turned off in response to the gain control signal if the capacitance values are lower than the predetermined threshold.

3. The semiconductor integrated circuit according to claim 2, wherein the switch element is turned on in response to the gain control signal at start of power supply to the semiconductor integrated circuit.

4. The semiconductor integrated circuit according to claim 1, wherein the inverting amplifier comprises:
an inverter that outputs the oscillation signal with an input connected to the first terminal;
an auxiliary inverter with an input connected to the input of the inverter and an output connected to an output of the inverter;
a feedback resistor with a first end connected to the input of the inverter and a second end connected to the output of the inverter; and
a damping resistor with a first end connected to the output of the inverter and a second end connected to the second terminal,
wherein the auxiliary inverter is driven in response to the gain control signal if the capacitance values are not lower than the predetermined threshold, and
the auxiliary inverter is stopped driving in response to the gain control signal if the capacitance values are lower than the predetermined threshold.

5. The semiconductor integrated circuit according to claim 1, wherein the waveform shaping circuit is an inverter that receives the oscillation signal from an input and outputs the clock signal from an output.

6. The semiconductor integrated circuit according to claim 1, wherein a capacitance information signal is outputted to the edge detecting circuit from outside of the semiconductor integrated circuit, the capacitance information signal determining whether or not the capacitance values of the first load capacitance and the second load capacitance are lower than the predetermined threshold.

7. The semiconductor integrated circuit according to claim 1, further comprising a capacitance detecting circuit that detects the capacitance values of the first load capacitance and the second load capacitance and outputs a capacitance information signal that determines whether or not the capacitance values are lower than the predetermined threshold.

8. The semiconductor integrated circuit according to claim 1, wherein the edge detecting circuit outputs the gain control signal that sets the gain of the inverting amplifier at the first value at start of power supply to the semiconductor integrated circuit.

9. The semiconductor integrated circuit according to claim 1, wherein the edge detecting circuit generates the gain control signal based on a capacitance information signal that determines whether or not the capacitance values of the first load capacitance and the second load capacitance are lower than the predetermined threshold.

10. The semiconductor integrated circuit according to claim 9, wherein the edge detecting circuit that receives the capacitance detection signal from a data terminal, receives the clock signal from a clock signal terminal, and outputs the gain control signal from an output.

11. An oscillation system comprising:
a first load capacitance with a first end connected to ground and a second end connected to a first terminal;
a second load capacitance with a first end connected to the ground and a second end connected to a second terminal;
a crystal resonator with a first end connected to the second end of the first load capacitance and a second end connected to the second end of the second load capacitance; and
a semiconductor integrated circuit that controls oscillation of a crystal resonator,
wherein the semiconductor integrated circuit comprises:
an inverting amplifier that generates an oscillation signal with an input connected to the first terminal and an output connected to the second terminal, the inverting amplifier fluctuating in gain in response to a gain control signal;
a waveform shaping circuit that shapes a waveform of the oscillation signal and outputs a clock signal to a clock signal output terminal; and
an edge detecting circuit that detects an edge of the clock signal and outputs the gain control signal at a time of the edge,
wherein the edge detecting circuit outputs the gain control signal that sets the gain of the inverting amplifier at a first value if capacitance values of the first load capacitance and the second load capacitance are not lower than a predetermined threshold, and
the edge detecting circuit outputs the gain control signal that sets the gain of the inverting amplifier at a second value lower than the first value if the capacitance values are lower than the predetermined threshold.

12. The oscillation system according to claim 11, wherein the inverting amplifier comprises:
an inverter that outputs the oscillation signal with an input connected to the first terminal;
a feedback resistor with a first end connected to the input of the inverter and a second end connected to an output of the inverter;
a first damping resistor with a first end connected to the output of the inverter and a second end connected to the second terminal;
a second damping resistor connected in parallel with the first damping resistor between the output of the inverter and the second terminal; and
a switch element connected in series with the second damping resistor between the output of the inverter and the second terminal, the switch element being turned on/off in response to the gain control signal,
wherein the switch element is turned on in response to the gain control signal if the capacitance values are not lower than the predetermined threshold, and
the switch element is turned off in response to the gain control signal if the capacitance values are lower than the predetermined threshold.

13. The oscillation system according to claim 12, wherein the switch element is turned on in response to the gain control signal at start of power supply to the semiconductor integrated circuit.

14. The oscillation system according to claim 11, wherein the inverting amplifier comprises:
an inverter that outputs the oscillation signal with an input connected to the first terminal;
an auxiliary inverter with an input connected to the input of the inverter and an output connected to an output of the inverter;
a feedback resistor with a first end connected to the input of the inverter and a second end connected to the output of the inverter; and
a damping resistor with a first end connected to the output of the inverter and a second end connected to the second terminal,
wherein the auxiliary inverter is driven in response to the gain control signal if the capacitance values are not lower than the predetermined threshold, and
the auxiliary inverter is stopped driving in response to the gain control signal if the capacitance values are lower than the predetermined threshold.

15. The oscillation system according to claim 11, wherein the waveform shaping circuit is an inverter that receives the oscillation signal from an input and outputs the clock signal from an output.

16. The oscillation system according to claim 11, wherein a capacitance information signal is outputted to the edge detecting circuit from outside of the semiconductor integrated circuit, the capacitance information signal determining whether or not the capacitance values of the first load capacitance and the second load capacitance are lower than the predetermined threshold.

17. The oscillation system according to claim 11, further comprising a capacitance detecting circuit that detects the capacitance values of the first load capacitance and the second load capacitance and outputs a capacitance information signal that determines whether or not the capacitance values are lower than the predetermined threshold.

18. The oscillation system according to claim 11, wherein the edge detecting circuit outputs the gain control signal that sets the gain of the inverting amplifier at the first value at start of power supply to the semiconductor integrated circuit.

19. The oscillation system according to claim 11, wherein the edge detecting circuit generates the gain control signal based on a capacitance information signal that determines whether or not the capacitance values of the first load capacitance and the second load capacitance are lower than the predetermined threshold.

20. The oscillation system according to claim 19, wherein the edge detecting circuit that receives the capacitance detection signal from a data terminal, receives the clock signal from a clock signal terminal, and outputs the gain control signal from an output.
